(19) United States
(12) Patent Application Publication
(10) Pub. No.: US 2016/0325532 A1
(43) Pub. Date: Nov. 10, 2016

(54) UV-PROTECTIVE FILM FOR OLEDS

(71) Applicants: COVESTRO DEUTSCHLAND AG, Leverkusen (DE); OSRAM OLED GMBH, Regensburg (DE)

(72) Inventors: Heinz Pudleiner, Krefeld (DE); Klaus MEYER, Dormagen (DE); Benjamin KRUMMACHER, Regensburg (DE); Simon SCHICKTANZ, Regensburg (DE); Daniel S. SETZ, Regensburg (DE)

(21) Appl. No.: 15/108,925

(22) PCT Filed: Jan. 20, 2015
(86) PCT No.: PCT/EP2015/051001

§ 371 Date: Jun. 29, 2016

(30) Foreign Application Priority Data
Jan. 21, 2014 (EP) 14152021.3

(51) Int. Cl. B32B 27/08; H01L 51/52; B32B 27/36; H01L 51/00; B32B 27/30

(52) U.S. Cl. CPC B32B 27/08; H01L 51/0034; B32B 27/308; B32B 27/365; H01L 51/0097; H01L 51/5275; B32B 2250/02; B32B 2250/24; B32B 2457/206; B32B 2307/412

(57) ABSTRACT

The present invention concerns a plastic foil, comprising at least one first layer of a plastic composition containing a first transparent plastic, as well as 0.01 to 15 wt. % transparent polymer diffusion particles, related to the total mass of the first layer, and at least one second layer of a plastic composition, containing a second transparent plastic and 0.01 to 5 wt. % a UV absorber, related to the total mass of the second layer, characterised in that the refraction index, determined according to DIN EN ISO 489 at 23° C. and 589 nm, of the second layer differs from the refraction index of the first layer by at least 0.6%. Further objects of the invention are the use of the plastic foil as an optical uncoupling foil, an organic radiation emitting construction element containing the plastic foil, as well as the use of the construction element as an organic light emitting diode (OLED).

The present invention concerns a plastic foil, comprising at least one first layer of a plastic composition, containing a first transparent plastic, as well as transparent polymer diffusion particles and at least one second layer of a plastic composition, containing a second transparent plastic and a UV absorber. Further objects of the invention are the use of the plastic foil as an optical uncoupling foil, an organic radiation emitting construction element, containing the plastic foil, as well as the use of the construction element as an organic light emitting diode (OLED).

Due to their low energy consumption, their long working life and their high light quality organic light emitting diodes (OLEDs) are known as a light source of the future. A large part of the light generated in OLEDs is however not uncoupled to the observer, i.e. in a useable way. The reasons for this are the optical characteristics of the materials used in OLEDs as well as the glass normally used as an OLED substrate. Instead the useable light flux is weakened by wave guidance and/or absorption in the relevant layers by a considerable factor. One main reason for this is the gap in optical thickness at the transition from glass to air. A total reflection of photons occurs on this border surface from a certain, material specific angle (dependent on colour and substrate). These photons can then no longer be made use of.

It is known in principle, for example from WO2005/018010, EP1406474, US2001/0026124 and US2004/0061107, that the use of diffusing elements can improve the uncoupling or light efficiency of an OLED.

WO2008/014739 and WO2010/146091 also describe radiation emitting construction elements comprising an uncoupling foil. The use of special uncoupling foils made of plastic can realise an increase in light efficiency and the homogeneity of the radiation capacity. It is however necessary that the foils have a certain surface structuring for this, the application of which is complex. The solutions envisaged by prior art also substantially influence the appearance of the construction elements due to the structuring of the surface of the uncoupling foil. An undesirable milky and reflecting surface therefore results in the switched-off condition.

It has also been observed with the radiation emitting construction elements according to prior art, in particular for large surface applications, that the colour impression will depend on the viewing angle of the observer of the light source (colour shift). A consistent colour impression irrespective of the viewing angle of the observer would however be of advantage.

As already mentioned above, OLEDs normally contain glass as the carrier material. This does however have a few other disadvantageous characteristics: glass is UV permeable to such an extent that damage to the active—partially photochemically sensitive—oreanic materials caused by UV light cannot be ruled out. Glass also tends to fracture under mechanical loads, representing a potential safety risk.

It was therefore the underlying task of the present invention to provide a plastic foil that can be used as an uncoupling foil for organic radiation emitting construction elements that guarantee a high uncoupling efficiency and also generate a good optical appearance in the switch-off condition at the same time. A consistent colour impression should also be guaranteed, which should be independent from the observation angle as much as possible. The plastic foil should also be scratch resistant, provide UV protection for the active organic materials and minimise the safety risk of glass as a carrier material when used in OLEDs.

This task is solved in accordance with the invention by a plastic foil, comprising at least one layer of a plastic composition, containing a first transparent plastic as well as 0.01 to 10 wt. % transparent polymer diffusion particles, related to the total mass of the first layer, and at least one second layer of a plastic composition, containing a second transparent plastic and 0.01 to 5 wt. % of a UV absorber, related to the total mass of the second layer, characterised in that the refraction index of the second layer differs by at least 1% from the refraction layer of the first layer.

All said refraction indices are determined according to DIN EN ISO 489 (at 23° C. and 589 am).

It has surprisingly been found that the plastic foils according to the invention lead to increased uncoupling efficiency compared to prior art when used as uncoupling foils in OLEDs, Thanks to the smooth and shiny surface of OLEDs equipped with the plastic foils according to the invention also have appealing optical characteristics in the switched-off condition. It has also surprisingly been found that the colour impression is also clearly more consistent and less dependent on the viewing angle of the observer. OLEDs equipped with the plastic foil according to the invention also display improved resistance against UV radiation and are scratch resistant. The plastic foil further holds together the glass of the carrier material in the form of a compound, and therefore reduces the security risk of a fracture.

In one preferred embodiment of the invention the refraction index of the second layer differs by at least 0.6%, more preferably at least 3%, and most preferably at least 6% from the refraction index of the first layer. The refraction index of the second layer preferably differs by a maximum of 20%, particularly preferably a maximum of 15%, and most particularly preferably a maximum of 10% from the refraction index of the first layer.

The refraction index of the second layer is also preferably lower than that of the first layer. In one preferred embodiment of the invention the refraction index of the second layer is at least 0.6%, more preferably at least 3%, and most preferably at least 6% lower than the refraction index of the first layer. The refraction index of the second layer is preferably a maximum of 20%, more preferably a maximum of 15%, and most preferably a maximum of 10% lower than the refraction index of the first layer.

In a further preferred embodiment of the invention the refraction index of the second layer differs by at least 0.01, more preferably by at least 0.04, and most preferably by at least 0.09 units from the refraction index of the first layer. The refraction index of the second layer preferably differs by a maximum of 0.30, more preferably by a maximum of 0.25, and most preferably by a maximum of 0.15 units from the refraction index of the first layer.

In a further preferred embodiment of the invention the refraction index of the second layer is at least 0.01, more preferably at least 0.04, and most preferably at least 0.09 units lower than the refraction index of the first layer. The refraction index of the second layer is preferably a maximum of 0.30, more preferably a maximum of 0.25, and most preferably a maximum of 0.15 units lower than the refraction index of the first layer.

The transparent plastic of the first layer is preferably selected from the group of polyacrylates, polymethacrylates, polymethylmethacrylates (PMMA; Plexiglas® from company Röhm), cycloolefin-copolymers (COC; Topas® from company Ticona); Zenoex® from company Nippon Zeon or Apel® from company Japan Synthetic Rubber, polysulfones (Ultrason@ from company BASF or Udel® from company Solvay), polyester, such as for example PET or PEN, polycarbonate, polycarbonate/polyester blends, for example PC/PET, polycarbonate/polycyclohexyl-methanolcyclohexane-dicarboxylate (PCCD; Xylecs® from company Sabic IP) and polycarbonate/polybutyl-enterephthalate (PBT) blends.

In one preferred embodiment of the invention the transparent plastic of the first layer is a polycarbonate, a polycarbonate/polyester blend, a polycarbonate/polycyclohexyl-methanolcyclohexane-dicarboxylate blend or a polycarbonate/polybutyl-enterephthalate blend, more preferably polycarbonate.

Suitable polycarbonates are all known polycarbonates. These can be homopolycarbonates, copolycarbonates and thermoplastic polyester carbonates.

They preferably have median molecular weights M of 18,000 to 40,000, preferably 22,000 to 36,000, more preferably 24,000 to 33,000, calculated by measuring the relative solution viscosity in dichloromethane or in mixtures of the same weight quantities of phenol/o-dichlorobenzene, calibrated with light diffusion.

Regarding the production of polycarbonates we refer, for example, to “Schnell, Chemistry and Physics of Polycarhonats, Polymer Reviews, Vol. 9, Interscience Publishers, New York, London, Sydney 1964”, and to “D. C. PREVORSEK, B. T. DEBONA and Y. KESTEN, Corporate Research Center, Allied Chemical Corporation, Moristown, N.J. 07960, ‘Synthesis of Poly(ester)carbonate Copolymers’ in Journal of Polymer Science, Polymer Chemistry Edition, Vol. 19, 75-90 (1980)”, and to “D, Freitag, U, Grigo, P. R. Müller, N. Nouvertne, BAYER AG, ‘Polycarbonates’ in Encyclopedia of Polymer Science and Engineering, Vol. 11, Second Edition, 1988, pages 648-718”, and lastly to “Dres. U. Grigo, K. Kircher and P. R. Müller ‘Polycarbonates’ in Becker/Braun, Kunststoff-Handbuch, Volume 3/1, Polycarbonates, Polyacetales, Polyesters, Celluloseesters, Carl Hanser Verlag Munich, Vienna 1992, pages 117-299”.

The production of polycarbonates is preferably realised according to the phase boundary method or the smelt transesterification method, and is described hereafter with reference to the phase boundary method as an example.

Compounds to be used as preferred starting compounds are bisphenols with the general formula.

HO—R—OH,

wherein R is a divalent organic fraction with 6 to 30 carbon atoms, containing one or more aromatic groups.

Examples of such compounds are bisphenols belonging to the group of dihydroxy-diphenyls, bis(hydroxyphenyl)alkanes, indanbisplienols, bis(hydroxyphenypether, bis(hydroxyphenyl)stilfones, bis(hydroxyphenyl)ketones and α,α′-bis(hydroxyphenyl)-diisopropylbenzols.

More preferred bisphenols belonging to the above mentioned compound groups are tetraalkylbisphenol-A, 4,4-(meta-phenyiendiisopropyl)diphenol(bisphenol M), 4,4-(para-phenylendiisopropyl)diphenol, 1,1-bis-(4-hydroxyphenyl)-3,3,5-trimethylcyclohexane (BP-TMC) and possibly mixture thereof.

The bisphenol compounds used according to the invention are preferably converted with carbonic acid compounds, in particular phosgene, or with diphenylcarbonate or dimethylcarbonate during the smelt transesterification process.

Polyester carbonates are preferably obtained through conversion of the bisphenol already mentioned, at least one aromatic dicarboxylic acid and possibly carbonic acid equivalents. Suitable aromatic dicarboxylic acids are, for example, phthalic acid, terephthalic acid, isophthalic acid, 3,3′- or 4,4′-diphenyldicarboxylic acid and benzoplienondicarboxylic acid. One part, up to 80 mol. %, preferably from 20 to 50 mol. % of the carbonate groups in the polycarbonates can be replaced with aromatic dicarboxylic acid.

Inert organic solvents used during with the phase boundary method are, for example, dichloromethane, the various dichloroethanes and chloropmpane compounds, tetrachloromethane, trichloromethane, chlorobenzene and chlorotoluol, whilst chlorobenzene or dichloromethane or mixtures of dichloromethane and chlorobenzene are preferably used.

The phase boundary reaction can be accelerated with catalysts such as tertiary amines, in particular N-alkylpiperidines or onium salts. Tributylamine, triethylamine and N-ethylpiperidine are preferably used. In the case of the smelt transesterification process the catalysts mentioned in DE-A 4 238 123 are preferably used.

The polycarbonates can be branched intentionally and in a controlled way by using small quantities of branching agents. Some suitable branching agents are: phloroglucine, 4,6-dimethyl-2,4,6-tri-(4-hydroxyphenyl)-heptene-2; 4,6-dimethyl-2,4,6-tri-(4-hydroxy-phenyl)-heptane; 1,3,5-tri-(4-hydroxyphenyI)-benzene; 1,1,1-tri-(4-hydroxyphenyl)-ethane; tri-(4-hydroxyphenyl)-phenylmethane; 2,2-bis-[4,4-bis-(4-hydroxyphenyl)-cyclohexyl]-propane; 2,4-bis-(4-hydroxyphenyl-isopropyl)-phenol; 2,6-bis-(2-hydroxy-5′-methyl-benzyl)-4-methylphenol; 2-(4-hydroxyphenyl)-2-(2,4-dihydroxyphenyl)-propane; hexa-(4-(4-hydroxyphenyl-isopropyl)-phenyl)-orthoterephthalic acid ester; tetra-(4-hydroxyphenyI)-methane; tetra-(4-(4-hydroxyphenyl-isopropyl)-phenoxy)-methane; α,α,′α″-tris-(4-hydroxyphenyl)-1,3,5-triisopropylbenzene; 2,4-dihydroxybenzoic acid; trimesinic acid; cyanurchloride; 3,3-bis-(3-methyl-4-hydroxyphenyl)-2-oxo-2,3-dihydroindol; 1,4-his-(4′,4″-dihydroxytriphenyl)-methyl)-benzene, and in particular: 1,1; 1-tri-(4-hydroxyphenyl)-ethane and bis-(3-methyl-4-hydroxyphenyl)-2-oxo-2,3-dihydroindol.

The 0.05 to 2 mol. %, related to the diphenols to be used as well, of branching agents or mixtures of branching agents can be used together with the diphenols, but can also be added at a later stage of the synthesis.

Phenols such as phenol, alkylphenols such as cresol and 4-tert.-butylphenol, chlorophenol, bromophenol, cumylphenol or their mixtures are preferably used in quantities of 1-20 mol. %, preferably 2-10 mol. % per mol of bisphenol as chain breaking agents. Preferred are phenol, 4-tert.-butylphenol or cumylphenol.

Chain breaking agents and branching agents can be added to the syntheses separately of also together with the bisphenol.

The production of the polycarbonates according to the smelt transesterification process is for example described in DE-A 4238 123.

Polycarbonates preferred according to the invention for the first layer of the plastic foil according to the invention are the homopolycarbonate based on bisphenol A, the homopolycarbonate based on 1,1-bis-(4-hydroxyphenyI)-3,3,5-trimethylcyclohexane and die copolycarbonates based on the two monomers bisphenol A and 1,1-bis-(4-hydroxyphenyl)-3,3,5-trimethylcyclohexane.

The transparent plastic of the first layer is more preferably a homopolycarbonate based on bisphenol A.

The proportion of transparent plastic in the plastic composition of the first layer preferably lies at 85 to 99.98 wt. %, more preferably at 90 wt. % to 99.98 wt. (?4), and most preferably at 97.5 wt. % to 99.98 wt. % related to the total mass of the first layer.

The first layer contains 0.01 to 15 wt. %, preferably 1 to 10.5 wt. %, more preferably 5 to 9 wt. % of transparent polymer diffusion particles, related to the total mass of the first layer.

The refraction index of the diffusion particles preferably differs by 0.6% or more, more preferably by 3% or more, and most advantageously by 6% or more from the refraction index of the transparent plastic of the matrix material of the first layer. The greater the difference, the more efficient the radiation deflection by means of the diffusion particles will normally be.

In a further preferred design the diffusion particles have an average diameter (median particle diameter) of at least 0.5 μm, preferably of at least 1 μm up to 100 μm, or even up to 120 μm, more preferably of 2 to 50 μm, and most preferably of 2 to 30 μm. “Average diameter” (median particle diameter) should be understood as the number average.

Diameters in the above sense of between 0.5 μm inclusive and 50 μm inclusive, preferably between 2 μm inclusive and 30 μm inclusive have been found to be particular suitable for an OLED.

The transparent polymer diffusion particles are preferably a free-flowing powder, preferably in a compacted form.

The diffusion particles can be admixed in static distribution to the form mass of the transparent plastic for the foil matrix prior to producing the foil.

Acrylates can be used as transparent diffusion particles. These preferably have a sufficiently high thermal stability, for example up to at least 300° C., to not be decomposed at the processing temperatures of the transparent plastic, preferably polycarbonate. Cross-linked acrylates are preferably used as diffusion particles. The products of series Techpolymer® from company Sekisui are used more preferably.

The diffusion particles should have no further functionalities that would lead to a breakdown of the polymer chain of the polycarbonate. Techpolyiner® from company Sekisui or Paraloin) from company Röhm & Haas can for example be used well for the pigmentation of transparent plastics. These product series offer a multitude of different types.

In a further design form of the invention the diffusion particles can be particles with a core shell construction, in particular polymer particles with a core shell morphology. These particles are preferably designed as solid particles, and not as hollow particles. The production of core/jacket polymer particles is described in EP-A 0 269 324 and in U.S. Pat. Nos. 3,793,402 and 3,808,180.

The diffusion particles can be designed as solid or hollow particles, whilst the diffusion particles are preferably solid particles.

Hollow particles are for example described in U.S. Pat. No. 5,053,436. The wall material consists of acrylate polymer and the interior is filled with ambient air.

The first layer can contain small quantities of a UV absorber. The first layer can contain 0.01 to 0.3 wt. %, preferably 0.01 to 0.1 wt. % of a UV absorber. The UV absorber is preferably an organic UV absorber and is for example selected from the group of benzotriazol derivatives, dimeric benzotriazol derivatives, triazine derivatives, dimeric triazine derivatives, diarylcyanoacrylates or mixtures of the above mentioned compounds. In one preferred design of the invention the UV absorber is a triazine derivative. The first layer preferably contains no UV absorber though.

The first layer preferably also contains 0.01 to 4 wt. %, more preferably 0.05 to 2 wt. %, and most preferably 0.1 to 1 wt. ° A) of an antistatic agent, related to the total mass of the first layer. Examples of suitable antistatic agents are cation-active compounds, for example quarteniary ammonium, phosphonium or sulfonium salts, anion-active compounds, for example alkylsulfonates, alkylsulfates, alkylphosphates, carboxylates in the form of alkali or alkaline earth metal salts, non-ionogenic compounds, for example polyethyleneglycol ester, polyethyleneglycol ether, fatty acid ester, ethoxylated fatty amines. Preferred antistatic agents are quarternary ammonium compounds. In one preferred embodiment of the invention the antistatic agent is diisopropyldimethyl-ammonium-perfluorhutane sulfonate.

Electrostatically generated deposits on the foil, which have a negative effect on the output side radiation capacity distribution, can be reduced through use of these antistatic agents.

The first layer preferably has a layer thickness of 100 to 300 μm, more preferably of 100 to 160 μm.

The surface of the first layer preferably has a gloss level, determined according to EN ISO 2813 (angle 60°) of >60, more preferably >90, and most preferably 95.

The surface of the first layer further has a roughness, determined according to ISO 4288, of 2 μm, more preferably 1 μm.

In a further, less preferred design the first layer can also have a structured and matt surface. In this case the matt surface is preferably formed by the surface of the plastic foil facing the construction element. This surface preferably has a gloss level of ≦50 and a roughness of ≧15 μm.

The plastic foil according to the invention comprises a second layer of a plastic composition with the following characteristics.

The proportion of transparent plastic in the plastic composition of the second layer preferably lies at 90 to 99.98 wt. %, more preferably at 92.5 to 99.98 wt. %, and most preferably at 95 wt. % to 99.98 wt. % related to the total mass of the second layer.

In one preferred embodiment of the design the transparent plastic of the second layer is a polyacrylate or polymethacrylate, more preferably a polymethacrylate, and most preferably a polyalkyltnethacrylate with alkyl chain lengths of fewer than 10 carbon atoms (—CₙH₂ₙ₊₁ with n<10). Most preferably it is polymethyl(meth)acrylate (PMMA, n=1).

Polymethyl(meth)acrylate (PMMA) as well as blends of PMMA or of impact-resistant PMMA can be used as polymethacrylates. They are available from Röhm GmbH under the brand name Plexiglas®. Polymethyl(meth)acrylate is understood both as polymers of methacrylic acid and its derivatives, for example its esters, and as polymers of acrylic acid and its derivatives as well as mixtures of the two above mentioned components.

Preferred are polymethyl(meth)acrylate plastics with a methylmethacrylate monomer proportion of at least 80 wt/%, preferably at least 90 wt. %, and possibly 0 wt. % to 20 wt. %, preferably 0 wt. % to 10 wt. % of second vinylic copolymerisable monomers such as for example C₁- to C₈-alkylesters of acrylic acid or methacrylic acid, for example methylacrylate, ethylacrylate, butylacrylate, butylmethacrylate, hexylmethacrylate, cyclohexylmethacrylate, also styrol and styrol derivatives such as for example [alpha]-methylstyrol or p-methylstyrol. Second monomers can be acrylic acid, methacrylic acid, maleic acid anhydride, hydroxyesters of acrylic acid or hydroxyesters of methacrylic acid.

The second layer preferably has a layer thickness of 15 to 60 μm, more preferably of 30 to 50 μm.

The second layer contains 0.01 to 10 wt. %, preferably 0.01 to 7.5 wt. %, and more preferably 0.01 to 5 wt. % of a UV absorber. The UV absorber is preferably an organic UV absorber and is for example selected from the group of benzotriazol derivatives, dimeric benzotriazol derivatives, triazine derivatives, dimeric triazine derivatives, diarylcyanoacrylates or mixtures of the above mentioned compounds. In one preferred design of the invention the UV absorber is a triazine derivative, more preferably a triazine with the general formula (I).

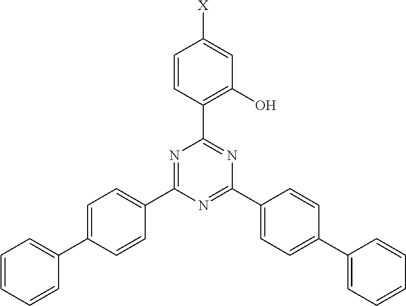

wherein X=means OR¹; OCH₂CH₂OR¹; OCH₂CH(OH)CH₂OR¹ or OCH(R)COOR³, and R¹ stands for branched or unbranched C₂-C₂₀-alkenyl, C₆-C₁₂-aryl or —CO—C₁-C₁₈-alkyl, R² is H or branched or unbranched C₁-C₈-alkyl, and R³ means C₁-C₁₂-alkyl; C₂-C₁₂-alkenyl or C₅-C₆-cycloalkyl.

In a particularly preferred design of the second layer according to the invention X═OR′, wherein R¹ has the above mentioned meaning, and X=is most preferably OR′, wherein R¹═CH₂CH(CH₂CH₃)C₄H₉.

Such biphenyl substituted triazines with the general formula I are known in principle from WO 96/28431; DE 197 39 797; WO 00/66675; U.S. Pat. No. 6,225,384; U.S. Pat. No. 6,255,483; EP 1 308 084 and FR2812299.

The second layer preferably contains 0.01 to 4.0 wt. %, more preferably 0.05 to 2.0 wt. °,6, and most preferably 0.1 to 1.0 wt. % of an antistatic agent, related to the total mass of the second layer. The antistatic agent is for example selected from the compounds listed for the first layer. In one preferred design of the invention the antistatic agent is diisopropyldimethyl-anamonium-perfluorobutane-sulfonate.

The surface of the second layer preferably has a gloss level, determined according to EN ISO 2813 (angle 60°) of ≧60, more preferably ≧90, and most preferably ≧95.

The surface of the second layer further has a roughness, determined according to ISO 4288, of ≦2 μm, more preferably <1 μm.

The gloss level of the foil surface is particularly important and influences the optical characteristics of the foil. The optical impression of the non-operational construction element in particular can be adjusted by means of the same.

In one special embodiment of the plastic foil according to the invention the second layer can comprise a coating. The coating is preferably a hard coat known to the person skilled in the art. The hard coat is more preferably based on a cross-linked transparent plastic. The coating preferably equips the surface of the plastic foil with a pencil hardness (determined according to ISO 15184) of ≧1H and <81-1, and more preferably of ≧2H and ≦5H. The coating can be applied directly onto the second layer without a primer. The coating can also contains a UV absorber identical to the UV absorber of the previously mentioned preferred embodiments.

The first layer as well as the second layer of the plastic foil according to the invention can also contain additives, such as for example processing agents. These can in particular include demoulding agents, flow improvers, stabilising agents, in particular thermostabilising agents and/or optical brighteners. Each layer can contain different additives or different concentrations of additives. The second layer preferably contains the demoulding agents.

Stabilising agents suitable for polycarbonates are preferably used. Suitable stabilising agents are for example phosphines, phosphites or stabilising agents containing Si and further compounds described in EP-A 0 500 496. Examples to be mentioned are triphenylphosphites, diplienylalkylphosphites, phenyldialkylphosphites tris-(nonylphenyl)phosphite, tetrakis-(2,4-di-tert-butylphenyl)-4,4′-biphenylen-diphosphonite, bis(2,4-dicumylphenyl)petaerythritoldiphosphite and triarylphosphite. Triphenylphosphine and tris-(2,4-di-tert.-butylphenyl)phosphite are particularly preferred.

Suitable demoulding agents are for example the esters or part esters of mono- to hexavalent alcohols, in particular of glycerine, of pentaerythritis or of guerbeta alcohols.

Monovalent alcohols are for example stearyl alcohol, palmityl alcohol and guerbeta alcohols, a divalent alcohol is for example glycol, a trivalent alcohol is for example glycerine, tetravalent alcohols are for example pentaerythrite and mesoerythrite, pentavalent alcohols are for example arabite, ribite and xylite, hexavalent alcohols are for example mannite, glucite (sorbitol) and dulcite.

The esters are preferably the monoesters, diesters, triesters, tetracsters, pentaesters and hexaesters or their mixtures, in particular statistical mixtures; of saturated aliphatic C₁₀- to C₃₆-monocarboxylic acids and possibly hydroxymonocarboxylic acids, preferably with saturated aliphatic C₁₄- to C₃₂-monocarboxylic acids and possibly hydroxymonocarboxylic acids.

Commercially available fatty acid esters, in particular of pentaerythrite and of glycerine, can contain less than 60% of different part esters, depending on the production method. Saturated aliphatic monocarboxylic acids with 10 to 36 C atoms are for example capric acid, lauric acid, myristic acid, palmitinic acid, stearic acid, hydroxystearic acid, arachnic acid, behenic acid, lignoceric acid, carotic acid and montaic acids.

The plastic foil according to the invention can also contain organic dyes, anorganic colour pigments, fluorescent dyes, and more preferably optical brighteners.

The first layer as well as the second layer of the plastic foil according to the invention can also contain wavelength conversion agents. Wavelength conversion agents are materials that are suitable for absorbing electromagnetic primary radiation, at least in part, and emitting the same as secondary radiation with a wavelength range that is at least partly different from the primary radiation. Electromagnetic primary radiation and electromagnetic secondary radiation can include one or more wavelengths and/or wavelength ranges of an infrared to ultraviolet wavelength range, in particular of a visible wavelength range. The spectrum of primary radiation and/or the spectrum of secondary radiation can be narrow-band here, which means that the primary radiation and/or the secondary radiation can have a single-colour or almost single-colour wavelength range. Alternatively the spectrum of the primary radiation and/or the spectrum of the secondary radiation can also be broadband, which means that the primary radiation and/or the secondary radiation can have a mixed-colour wavelength range, wherein the mixed-colour wavelength range can have a continuous spectrum or several discrete spectral components with different wavelength. The electromagnetic primary radiation can for example have a wavelength range of an ultraviolet to blue wavelength range, whilst the electromagnetic secondary radiation can have a wavelength range of a blue to red wavelength range. More preferably the primary radiation and the secondary radiation can be overlaid to give a white-coloured lighting impression. For this the primary radiation can preferably give a blue-coloured lighting impression and the secondary radiation a yellow-coloured lighting impression, which can be generated by spectral component of the secondary radiation in the yellow wavelength range and/or spectral components in the green and red wavelength ranges.

The wavelength conversion material can contain one or more of the following materials here: garnets of rare earths and alkaline earth metals, for example YAG:Ce³⁺, also nitrides, nitrous silicates, zions, zialones, aluminates, oxides, halophosphates, orthosilicates, sulfides, vanadates, perylenes, coumarin and chlorosilicates.

The wavelength conversion layer can further comprise suitable mixtures and/or combinations that for example contain the said wavelength conversion agents. In this way it may for example be possible that the wavelength conversion layer is absorbed in a blue first wavelength range and emitted in a second wavelength range, which comprises green and red wavelengths and/or yellow wavelength ranges, as described above.

The plastic foil according to the invention preferably has a total thickness of 120 to 400 pan, preferably of 200 μm.

When in doubt foil can be considered a layer or a layer compound that will not support its own weight and it therefore not designed to be unsupported, and is in particular flexible.

The first and the second layer can be joined through coextrusion or by means of connecting separate prefabricated foils, for example through masking or laminating, for producing the plastic foil according to the invention. In one preferred embodiment of the invention the first and the second layer are of a coextruded design.

For producing the plastic foil through extrusion the plastic granulate, for example the polycarbonate granulate, is preferably supplied to a filling funnel of an extruder and enters the plastification system, consisting of a screw and cylinder, via the same. The plastic material can be transported and smelted in the plastification system. The plastic smelt is preferably pressed through a fishtail nozzle, A filter means, a smelting pump, stationary mixing elements and further components can be arranged between the plastification system and the fishtail nozzle. The smelt exiting from the nozzle is preferably applied to a polishing stack, A smooth and/or glossy surface is preferably produced with polished metal cylinders, A rubber cylinder can also be used for a one-sided structuring of the foil surface of the first layer. Final shaping can take place in the cylinder gap of the polishing stack. The rubber cylinders preferably used for structuring the foil surface are described in U.S. Pat. No. 4,368,240. Forming can finally be completed through cooling, namely alternately on the smoothing cylinders and in ambient air. The further means of the plastification system also serve for the transport, the possibly desired application of protective foils, and the winding up of the extruded foils.

By using one or more side extruders and suitable smelt adapters on front of the fishtail nozzle, polymer smelts of different compositions can be overlaid and thus produce multi-layered foils (see for example EP-A 0 110 221 and EP-A 0 110 238).

The production of the second, and possibly also the third layer, according to the invention is preferably realised by producing a compound (a) from (a1) the second transparent plastic and (a2) a UV absorber, preferably a biphenyl substituted triazine with the general formula (I). The compound (a) can then either (i) be coextruded with the first transparent plastic in a way that a thin UV protection layer of compound (a) adheres well to the surface of the first transparent plastic, or (ii) compound (a) can be processed further to form a thin foil that is then back injected or laminated with a foil of the first transparent plastic to form a well adhering compound. In an alternative embodiment variant the second, and possibly also a third layer can be painted onto the first layer, or possibly the second layer.

A further object of the invention is the use of the plastic foil according to the invention, in particular as an optical diffusion or uncoupling foil in organic light emitting diodes (OLED).

A further object of the invention is an organic, radiation emitting construction element with an active organic layer formed for generating radiation and one or two radiation uncoupling sides, characterised in that a plastic foil according to the invention is arranged on the radiation uncoupling side or sides of the construction element.

In a preferred embodiment of the invention the construction according to the invention comprises a substrate, on which the organic layer is arranged. The plastic foil can here be arranged on the side of the substrate facing away from the organic layer, on the same side on which the organic layer is also applied, or also on both sides. The plastic foil is preferably connected with the substrate. The first layer of the plastic foil is also preferably arranged to face the substrate, and the second layer to face away from the substrate.

A further object of the invention is the use of the construction element according to the invention as an organic light emitting diode (OLED).

The active layer is here expediently formed by means of an organic layer, comprising an organic (semi)conductive material. The organic layer for example contains a (semi)conductive polymer and/or comprises at least one layer with a (semi)conductive molecule, in particular a low molecular molecule.

A prefabricated OLED can in particular comprise electrodes for electric contacting and alternatively, or additionally, a capsule protecting the organic layer, which for example protects the organic layer against moisture.

In one preferred design the construction element comprises a substrate, on which the active organic layer is arranged. The substrate expediently stabilises the active layer mechanically.

The substrate can in particular be formed by a layer onto which the organic layer, and possibly electrodes for electric contacting and/or further elements of the construction element are applied.

The plastic foil is preferably connected with the substrate. Thanks to the normally high mechanical stability of the substrate compared with a foil, the plastic foil can be affixed to the substrate very easily in a stable way, and preferably permanently. The substrate is expediently of an unsupported design.

Alternatively the substrate can be of a flexible design. A foil, in particular a foil made of plastic, for example a PMMA foil, is for example suitable for a flexible design. The mechanical stability of the substrate/plastic foil compound can be increased with the plastic foil according to the invention compared to a flexible substrate that is not equipped with a plastic foil.

The substrate can for example comprise glass, quartz, metal, metal foils, foils made of plastic, semi-conductor wafers such as silicon wafers or a Germanium wafer or a wafer based on phosphorous and/or nitrogen containing semi-conductor materials or any other suitable substrate material.

In one preferred embodiment of the construction element according to the invention the substrate is permeable for the radiation generated by the active layer, thus in particular made from a radiation permeable material. The side of the substrate facing away from the active layer can form a radiation emission surface of the construction element in this way. The substrate for example contains a glass. A glass substrate is in particular often used with OLEDs.

The substrate can further be designed in an electrically insulating way. The electric contacting of the construction element in this case preferably takes place on the side of the substrate facing away from the plastic foil.

The substrate can further be equipped substantially all over with the plastic foil. The plastic foil preferably covers at least the active organic layer completely.

In a further preferred embodiment the first layer of the plastic foil is matched to the refraction index of the construction element. The radiation transition from radiation from the construction element to the plastic foil is made easier in this way, and reflection losses at the boundary surface(s) between construction element and plastic foil are reduced. The refraction index of the first layer differs for this refraction index matching from that of the transparent plastic of the first layer, preferably by 20% or less, more preferably by 10% or less from the refraction index of the material arranged on the construction element, in particular the refraction index of the substrate, in a case where diffusion particles are installed.

A corresponding suitable material can be used for the first layer of the plastic foil for this refraction index matching. A polycarbonate is for example particularly suitable for refraction index matching with a glass substrate.

Alternatively, or additionally, a refraction index matching material, for example an optical gel arranged between the first layer of the plastic foil and the substrate, can be used for refraction index matching. With preference the refraction index matching material lessens the refraction index gap from substrate to the first layer of the plastic foil.

In a further preferred design the plastic foil is affixed to the construction element. The plastic foil is preferably affixed to the construction element, in particular the substrate, by means of an adhesive agent or the plastic foil is laminated onto the construction element, in particular onto the substrate. If an adhesive agent is used, this can with preference also serve as the refraction index matching material.

In a further preferred design the compound substrate that comprises the plastic foil and the substrate is stabilised by means of the plastic foil in such a way that the compound substrate itself is mechanically stabilised by the plastic foil even if the substrate is damaged.

This is particularly expedient if the substrate is made from a material that may fracture, for example glass. A fractured substrate can be held together by means of the plastic foil. The plastic foil is expediently designed with a suitable mechanical stability for this and is mechanically stable, and preferably permanently connected with the substrate. The total stability of the compound substrate, and also that of the compound construction element, can thus be increased in an advantageous way with the plastic foil according to the invention. The risk of injuries caused by fragments whilst handling the construction element is also reduced.

In a further preferred design the construction element is envisaged for lighting, in particular for general lighting purposes. The construction element can for example be used for interior room lighting, for external room lighting or in a signal lamp.

The construction element is preferably designed for generating visible radiation, in particular for use as general lighting. The uncoupling side luminance can be increased substantially with the plastic foil according to the invention.

The invention will now be described in more detail with reference to the following examples without being limited to the same. The examples according to the invention merely represent preferred embodiments of the present invention.

### EXAMPLES

### Substances Used

Macrolon 2600 000000:

Medium viscosity, high viscosity bisphenol A polycarbonate with an MVR of 12.5 cm³/10 min (according to ISO 1133 up to 300° C. and 1.2 kg)

Tinuvin 1600:

UV protection agent from company Ciba Specialty Chemicals (biphenyl substituted triazine with the formula I with X═OCH₂CH(CH₂CH₃)C₄H₉)

Plexiglas 8N:

PMMA with an MVR of 3 cm³/10 min (according to ISO 1133 at 230° C. and 3.8 kg) and a weight average molecular weight M_{w} of 124 kg/mol (determined by means of gel permeation chromatography at 23° C. in tetrahydrofuran; calibration to polstyrol norms of company Röhm GmbH & Co. KG).

### Example 1

### Production of a Diffusion Master Batch Through Compounding

The production of the master batch was realised with conventional twin-coil compounding extruders (for example ZSK 32) at the processing temperatures that are normal for polycarbonate, of 250 to 330° C.

A master batch with the following composition was produced:
80 wt. % Macrolon® 2600 000000 (polycarbonate (PC) from company Bayer MaterialScience AG)
20 wt. % cross-linked spherical methylmethacrylate particles (Techpolymer® BMSA-18GN from company Sekisui) with a particle size of 0.5 to 5 μm and an average particle size of approx. 2 μm.

### Example 2

### Production of Tinuvin 1600 UV Protection Compound

Production of the Tinuvin 1600 UV protection compound (granulate) was realised with a conventional twin-coil compounding extruder at the processing temperatures that are normal for polymethylmethacrylate, of 230 to 285° C.

A master batch with the following composition was produced:

Plexiglas 8N from company Evonik with a wt. % proportion of 95

Tinuvin 1600 as a colourless powder with a wt. % proportion of 5.

15 kg powder compound, consisting of 10 kg Plexiglas 8N granulate (average particle diameter approx. 0.8 mm) and 5 kg Tinuvin 1600, equaling 5 wt. %) was added to 85 kg Plexiglas 8N in a twin-coil extruder (ZSK 32) at a rotation speed of 190 min⁻¹ and a throughput of 50 kg/h. The mass temperature was 278° C. and the resulting granulate was clear and transparent.

### Examples 3 to 6

### Production of a Coextruded Foil

Foil Coextrusion

The equipment used consisted of
an extruder with a coil with a 105 mm diameter (D) and a length of 41×D. The coil includes a degassing zone;
a coextruder for applying the covering layer, with a coil of a length of 41 D and a diameter of 35 mm
a crosshead die;
a special coextrusion fishtail nozzle with a width of 1500 mm;
a three-cylinder polishing stack with horizontal cylinder alignment, wherein the third cylinder is pivotable by +/−45° from the horizontal;
a roller track;
a means for the double-sided application of protective foil;
a removal means
a winding station.

The granulate of the base material was supplied to the main extruder via the filling funnel. Smelting and transport of the relevant material took place in the relevant plastification system cylinder/coil. Both material smelts were combined in the coextrusion nozzle. From the nozzle the smelt passes to the polishing stack, the cylinders of which have the temperature listed in Table 1. Final shaping and cooling of the material takes place on the polishing stack. Polished chrome cylinders were used for polishing the surfaces. The foil is then transported through an outlet, the protective foil is applied on both sides, and the foil is wound up.

The following process parameters were selected:

TABLE 1

| Temperature main extruder | 295° C. +/− 5° C. | |
|---|---|---|
| Temperature of coextruder | 270° C. +/− 5° C. | |
| Temperature of crosshead die | 285° C. +/− 5° C. | |
| Temperature of nozzle | 300° C. +/− 5° C. | |
| Rotation speed of main extruder | 60 | min⁻¹ |
| Rotation speed of coextruder | 31 | min⁻¹ |
| Temperature of cylinder 1 | 76° | C. |
| Temperature of cylinder 2 | 73° | C. |
| Temperature of cylinder 3 | 140° | C. |
| Outlet speed | 14.6 | m/min |

Main Extruder:

A compound with the following composition was mixed:
Diffusion master batch from example 1 and polycarbonate Macrolon 2600 000000 from company Bayer MaterialScience AG at a ration according to column 2 “main extruder” of Table 2

Coextruder:

A compound (coextruder) with the following composition was mixed:

37.5 wt. % Tinuvin 1600 UV protection master batch and 62.6 wt. % polycarbonate Macrolon 2600 000000 from company Bayer Material Science AG

A foil with a gloss level of >95 on both sides, determined according to EN ISO 2813 (angle 60°) and a roughness of <0.5 μm, determined according to ISO 4288, was extruded. The foil had a total layer thickness of 200 μm, wherein the thickness of the base layer was 160 μm and that of the coextrusion layer 40 μm.

The thickness of the coating obtained in this way was determined by means of an Eta SD 30 from company Eta Optik GmbH.

TABLE 2

| | Main extruder | Coextruder |
|---|---|---|
| Example 3 | 160 μm | 40 μm |
| | 20% Compound from example | 37.5% Compound |
| | 1 + 80% M.2600 | (coextruder) + |
| | | 62.5% PMMA 8N |
| Example 4 | 160 μm | 40 μm |
| | 30% Compound from example | 37.5% Compound |
| | 1 + 70% M.2600 | (coextruder) + |
| | | 62.5% PMMA 8N |
| Example 5 | 160 μm | 40 μm |
| | 37.5% Compound from | 37.5% Compound |
| | example 1 + 62.5% M.2600 | (coextruder) + |
| | | 62.5% PMMA 8N |
| Example 6 | 160 μm | 40 μm |
| | 50% Compound from example | 37.5% Compound |
| | 1 + 50% M.2600 | (coextruder) + |
| | | 62.5% PMMA 8N |

### Example 7

### Comparison Example, not According to the Invention

A compound with the following composition was mixed:

50 wt. % diffusion master batch from example 1 and 50 wt. % polycarbonate Macrolon 2600 000000 from company Bayer MaterialScience AG

From this a 100 μm thick foil was extruded, which is smooth on both sides and has a gloss level of >95, determined according to EN ISO 2813 (angle 60°) and a roughness of <0.5 μm, determined according to ISO 4288.

### Example 8

### Application Technical Investigations

A double-stacked OLED designed as a “bottom emitter” with an aluminium cathode and a light area of 1.68 cm² was used as a test OLED and was powered with 2.5 mA/cm² (the measured voltage was 5.7 V).

Foils according to examples 3 to 7 were glued to the test OLED by means of an adhesive agent. For this the liner was removed from an adhesive agent (OCA 8212 from company 3M) and the adhesive agent laid onto the foil. The side on which the liner had been removed faced the first layer of the foil, which contained polycarbonate. The adhesive agent was laminated onto the foil with a manual roller. A correspondingly large sample was cut from the foil and the liner removed from the side of the adhesive agent facing away from the foil. The foil/adhesive compound was aligned to face the OLED substrate with the exposed adhesive agent side, laid onto the same and laminated to the OLED with the manual roller.

Determination of Optical Parameters (Table 3):

Peff [1 m/W]: Efficiency of the OLED light flux of a test OLED (active surface area 1.68 cm², operated at a flux density of 2.00 m/A*cm²). The light flux of the OLED [photometrically weighted 4 in 1 m] was determined in an integrating sphere, connected with a spectrometer via a glass fibre. Direct current was supplied with a high-precision laboratory mains adapter and the voltage applied measured with the same unit. The product of current and voltage results in the necessary electric capacity.

Ratio 1: Efficiency ratio compared to reference OLED without foil.

Delta_C: The angle dependent OLED emission was measured by means of a goniometer with fibreglass spectrometer. The angle dependent recorded emission equals colour coordinates (within the u′-v′ range). The transformation of the determined colour values into u′ v′ coordinates is realised according to DIN EN ISO 11664-5 (equation (4)). The colour coordinates were determined for an angle range of 0° to 75° of the component normal. These colour coordinates were then examined in the form of 30° segments. The first examination took place between 70°-40′, the last examination took place between 30°-0°. The maximum colour distance between two colour coordinate pairs was determined for each 30° segment (which represent measurements at two different angles). The maximum colour distance (in u′ v′ coordinates) found during the examination of all segments was Delta_C.

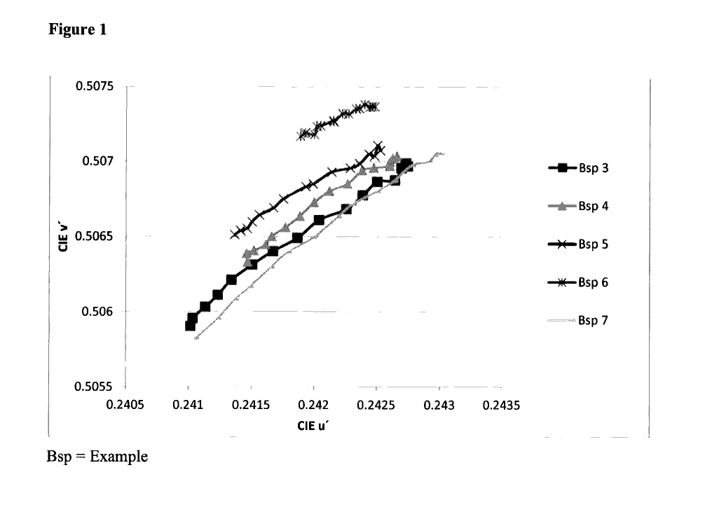

All results of the angle dependent measurements are illustrated in FIG. 1.

TABLE 3

| | Data from | | |
|---|---|---|---|
| | integrating | | |
| | sphere | | |
| | Peff [lm/W] | Ratio1 | Delta_C |
| without foil | 26.00 | 1.00 | 0.0231 |
| Example 3 | 33.20 | 1.28 | 0.0012 |
| Example 4 | 33.10 | 1.27 | 0.0009 |
| Example 5 | 32.70 | 1.26 | 0.0008 |
| Example 6 | 31.90 | 1.23 | 0.0003 |
| Example 7 | 32.00 | 1.23 | 0.0012 |

It is clear from Table 3 that the OLEDs equipped with foils 3 to 6 according to the invention display high efficiency, and foils 3 to 5 even display a clearly improved efficiency compared with the comparison foil 7. FIG. 1 shows that the OLEDs equipped with foils 3 to 6 according to the invention display a consistent colour impression that is mostly independent from the observer's viewing angle. A clear improvement of the colour impression compared with comparison foil 7 can be realised with foils 4 to 6.

1.-15. (canceled)

16. A plastic foil, comprising at least one first layer of a plastic composition containing a first transparent plastic, as well as 0.01 to 15 wt. % transparent polymer diffusion particles, related to the total mass of the first layer, and at least one second layer of a plastic composition, containing a second transparent plastic and 0.01 to 5 wt. % of a UV absorber, related to the total mass of the second layer, wherein the refraction index, determined according to DIN EN ISO 489 at 23° C. and 589 nm, of the second layer differs from the refraction index of the first layer by at least 0.6%.

17. The plastic foil according to claim 16, wherein the refraction index of the second layer differs from the refraction index of the first layer by at least 3%.

18. The plastic foil according to claim 16, wherein the refraction index of the second layer is lower than that of the first layer.

19. The plastic foil according to claim 16, wherein the transparent plastic of the first layer contains polycarbonate, and preferably is polycarbonate.

20. The plastic foil according to claim 16, wherein the transparent plastic of the second layer is a polyalkyl(meth)acrylate, preferably polymethyl(meth)acrylate.

21. The plastic foil according to claim 16, wherein the first layer contains 1 to 10.5 wt. % of transparent polymer diffusion particles, related to the total mass of the first layer.

22. The plastic foil according to claim 16, wherein the first layer contains 5 to 9 wt. % of transparent polymer diffusion particles, related to the total mass of the first layer.

23. The plastic foil according to claim 16, wherein the UV absorber is an organic UV absorber.

24. The plastic foil according to claim 16, wherein the first and the second layer are of a coextruded design.

25. The plastic foil according to claim 16, wherein the second layer comprises a coating.

26. The plastic foil according to claim 16, wherein the second layer has a layer thickness of 20 to 60 μm, preferably of 30 to 50 μm.

27. A method comprising utilizing the plastic foil according to claim 16 as an optical uncoupling foil.

28. An organic radiation emitting construction element with an organic layer designed for generating radiation and one or two radiation uncoupling sides, wherein a plastic foil according to claim 16 is arranged on one or both of the radiation uncoupling sides of the construction element.

29. The construction element according to claim 28, wherein the element comprises a substrate on which the organic layer is arranged, wherein the plastic foil is applied on the side of the substrate facing away from the organic layer, on the side on which the organic layer is also applied, or also on both of these sides, and the first layer of the plastic foil is arranged to face the substrate and the second layer to face away from the substrate.

30. An organic light emitting diode (OLED) comprising the construction element according to claim 28
